(19) United States
(12) Patent Application Publication
(10) Pub. No.: US 2022/0085306 A1
(43) Pub. Date: Mar. 17, 2022

(54) ELECTRONIC DEVICE

(71) Applicant: InnoLux Corporation, Miao-Li County (TW)

(72) Inventors: Huan-Kuang PENG, Miao-Li County (TW); Kun-Yi LIN, Miao-Li County (TW); Hsin-Hsu SHEN, Miao-Li County (TW); Shih-Hsiung WU, Miao-Li County (TW); Sheng-Nan FAN, Miao-Li County (TW); Chiu-Lien YANG, Miao-Li County (TW)

(21) Appl. No.: 17/405,100

(22) Filed: Aug. 18, 2021

(30) Foreign Application Priority Data
Sep. 17, 2020 (CN) 202010980216.4

(51) Int. Cl. H01L 51/00; G02F 1/1333; H01L 51/52

(52) U.S. Cl. CPC H01L 51/0097; H01L 51/5237; G02F 1/133305

(57) ABSTRACT

An electronic device is provided, including a first substrate, a second substrate and a blocking component. The second substrate is opposite to the first substrate. The second substrate has a cutting edge extending along a cutting direction. The blocking component is disposed between the first substrate and the second substrate. The blocking component extends along the cutting direction and is disposed corresponding to the cutting edge.

### CROSS REFERENCE TO RELATED APPLICATIONS

This application claims priority of China Patent Application No. CN 202010980216.4, filed on Sep. 17, 2020, the entirety of which is incorporated by reference herein.

### TECHNICAL FIELD

Some embodiments of the present disclosure relate to an electronic device, and, in particular, to an electronic device with a high reliability.

### BACKGROUND

Recently, flexible substrates with good bending properties have been widely used in various electronic devices to meet the requirements of users. Whether the wafer is being divided into independent chips or a thin film material is removed in a specific pattern, it is necessary to use a cutting process.

Generally, such a cutting process would be either a mechanical cutting process or a laser cutting process. However, mechanical cutting processes are limited by the slow cutting speed and the easy generation of cutting force, which can damage the object being cut. In addition, as the thickness of the substrate gradually becomes thinner, the cracks caused by the cutting process can increase rapidly. Therefore, a laser cutting process has been developed that can more accurately control the yield of the cutting process.

However, although the laser cutting process can be operated more easily than a mechanical cutting process, the laser cutting process still has a problem of heat damage at the cutting edge caused by the high laser power. The laser power is difficult to adjust finely. The non-cutting region may be damaged by the laser beam. Therefore, after the laser cutting process, the electronic device may include a heat-damaged region, which may reduce the overall reliability of the electronic device.

Therefore, although conventional electronic devices have gradually met their intended purposes, they have not fully met the requirements in all respects. Therefore, there are still some problems to be overcome with regard to electronic devices.

### SUMMARY

The present disclosure achieves the purpose of improving the reliability of the electronic device and/or increasing the process window of the laser cutting process by further providing a blocking component.

According to some embodiments of the present disclosure, an electronic device is provided. The electronic device includes a first substrate, a second substrate and a blocking component. The second substrate is opposite to the first substrate. The second substrate has a cutting edge extending along a cutting direction. The blocking component is disposed between the first substrate and the second substrate. The blocking component extends along the cutting direction and is disposed corresponding to the cutting edge.

The electronic devices of the present disclosure may be applied in various types of electronic devices with flexible substrate. In order to make the features and advantages of some embodiments of the present disclosure more understand, some embodiments of the present disclosure are listed below in conjunction with the accompanying drawings, and are described in detail as follows.

### BRIEF DESCRIPTION OF THE DRAWINGS

Through the following detailed description and the accompanying drawings, a person of ordinary skill in the art will better understand the viewpoints of some embodiments of the present disclosure. It should be noted that, in accordance with standard practice in the industry, various features are not drawn to scale and are used for illustration purposes. In fact, the dimensions of the various features may be arbitrarily increased or reduced for clarity of discussion.

FIG. 1 is a schematic top view of an electronic device according to some embodiments of the present disclosure.

FIGS. 2A to 2C are schematic cross-sectional views of electronic devices according to some embodiments of the present disclosure.

FIGS. 3A to 3C are schematic cross-sectional views of electronic devices according to some embodiments of the present disclosure.

FIG. 4 is a schematic top view of an electronic device according to some embodiments of the disclosure.

FIG. 5 is a schematic cross-sectional view of an electronic device according to some embodiments of the disclosure.

FIGS. 6A to 6C are schematic cross-sectional views of an electronic device according to some embodiments of the disclosure.

FIG. 7 is a schematic cross-sectional view of an electronic device according to some embodiments of the disclosure.

### DETAILED DESCRIPTION

The following disclosure provides many different embodiments or examples for implementing different features of the electronic device disclosed herein. Specific examples of each feature and its configuration are described below to simplify the embodiments of the present disclosure. Naturally, these are examples and are not intended to limit the present disclosure. For example, if the description mentions that the first feature is formed on the second element, it may include an embodiment in which the first feature and second feature are in direct contact, or may include an embodiment in which additional feature is formed between the first feature and the second feature thereby the first feature and the second feature do not directly contact. In addition, some embodiments of the present disclosure may repeat reference numerals and/or letters in different examples. Such repetition is for conciseness and clarity, and is not used to indicate the relationship between the different embodiments and/or aspects discussed herein. The spatial terms mentioned herein, such as “upper”, “lower”, “front”, “rear”, “left”, “right”, and the like, are directions with reference to the drawings. Therefore, the spatial terms are used to illustrate, but not to limit the present disclosure.

In some embodiments of the present disclosure, terms related to bonding and connecting, such as “connect”, “interconnect”, and the like, unless specifically defined, may refer that two structures are in direct contact, or may also refer to two structures is not in direct contact wherein another structure is disposed between the two structures. The terms related to bonding and connecting may also include the embodiments where both structures are movable or both structures are fixed. In addition, the terms “electrically connect” and “coupling” include any direct and indirect electrical connection means.

In addition, the “first”, “second”, and the like mentioned in the specification or claims are used to name different elements or distinguish different embodiments or scopes and are not used to limit the upper limit or lower limit of the elements and are not used to limit the manufacturing order or the arrangement order of the elements.

Herein, the terms “about”, “substantially” and the like usually mean within ±20% of a given value or a given range, for example, within ±10%, within 5%, within 3%, within 2%, within 1%, or within 0.5%. The value provided in the specification is an approximate value, that is, without specific description of “about”, “substantially” and the like, the meanings of the terms may still be implied.

Some modifications of the embodiment are described below. In the different drawings and illustrated embodiments, similar reference numerals are used to designate similar features. It should be understood that additional operations may be provided before, during, and after the method, and some of the operations that are described may be deleted or replaced with other embodiments of the method.

Herein, an X-axis, a Y-axis, and a Z-axis are not limited to three axes of a rectangular coordinate system, such as the X, Y, and Z-axes, and may be interpreted in a broader sense. For example, the X-axis, the Y-axis, and the Z-axis may be perpendicular to one another, or may represent different directions that are not perpendicular to one another. For ease of description, the X-axis direction is the width direction, the Y-axis direction is the length direction, and the Z-axis direction is the thickness direction. Hereinafter, the direction of laser cutting is referred to as the cutting direction, so the cutting edge extends along the cutting direction after being cut. It should be noted that, in an embodiment of the present disclosure, the cutting direction extends along the Y-axis direction, but it is not limited thereto. The cutting direction may be the X-axis direction, the Y-axis direction, the Z-axis direction, any combination thereof, or any direction in which a cut needs to be made. It should also be noted that, for ease of understanding, the width of the cutting edge is exaggerated in the figures.

In some embodiments, the electronic device of the present disclosure may include a display device, an antenna device, a sensing device, a light-emitting device, a touch display, a curved display, or a free shape display, but not limited thereto. The electronic device may be a bendable, flexible or curved electronic device. Here, the term “flexible” means that the electronic device (ED) may be curved, bent, folded, rolled, flexed, stretched, and/or made to undergo another, similar deformation, hereinafter referred to as “flexible,” to refer to the above-mentioned deformations. For example, the electronic device may include liquid crystal (LC), light emitting diode, quantum dot (QD), fluorescence, phosphor, another suitable display media, or some combination of the materials listed above, but it is not limited thereto. For example, the light emitting diode may include an organic light emitting diode (OLED), mini light emitting diode (mini LED), micro light emitting diode (micro LED) or quantum dot (QD, for example, QLED, QDLED), or another suitable material, and the materials may be combined arbitrarily, but it is not limited thereto. The display device may include, for example, a spliced display device, but it is not limited thereto. The antenna device may be, for example, a liquid crystal antenna, but it is not limited thereto. The antenna device may include, for example, an antenna spliced device, but it is not limited thereto. It should be noted that the electronic device may be any combination of the foregoing examples, but it is not limited thereto. In addition, the shape of the electronic device may be rectangular, circular, polygonal, a shape with curved edges, or another suitable shape. The electronic device may have a peripheral system, such as a driving system, a control system, a light source system, a shelf system, or the like to support the display device, antenna device or spliced device.

In other words, the electronic device including a blocking component of the present disclosure may be applied in any electronic device including a flexible substrate, for example: LCD such as TFT-LCD, QLED, OLED, Micro-LED, and the like, but it is not limited thereto. In some embodiments, the electronic device including the blocking component of the present disclosure may be applied to any process that requires performing a laser cutting, for example: applied to the back-end IC manufacturing process, or applied to the removal process of the material with a specific pattern on the film material, but it is not limited thereto. The blocking component of the present disclosure may be disposed to correspond to the cutting edge during any process stage.

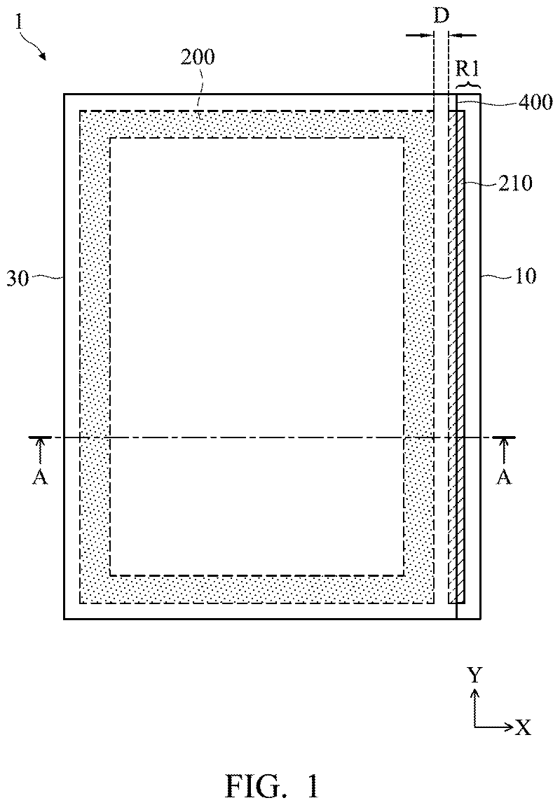

Referring to FIG. 1, which is a schematic top view of the electronic device according to some embodiments of the present disclosure, when viewed along the top view direction (Z direction). An electronic device 1 may include a first substrate 10, a second substrate 30, and a blocking component 210. The first substrate 10 may be a flexible substrate, but it is not limited thereto. In some embodiments, the first substrate 10 may be further provided with a transistor (not shown) for controlling pixels, such as a thin film transistor (TFT) array. The first substrate 10 and the second substrate 30 may be disposed opposite to each other. In some embodiments, the second substrate 30 and the first substrate 10 may be disposed correspondingly. The second substrate 30 may be a flexible substrate. In some embodiments, a color filter layer may be optionally disposed in or on the second substrate 30. For example, the color filter layer may include a red filter unit, a green filter unit, and a blue filter unit, any other suitable color filter unit, or a combination thereof. The first substrate 10 and the second substrate 30 may be transparent or opaque, and the materials of first substrate 10 or the second substrate 30 may include polymer materials and/or adhesive materials such as polyimide (PI), polycarbonate (PC), polyethylene terephthalate (PET), or the like, but it is not limited thereto. The first substrate 10 may also include thin glass or any suitable material. In other embodiments, the color filter layer may also be disposed on the first substrate 10, but the disclosure is not limited thereto.

In some embodiments, the blocking component 210 may be disposed between the first substrate 10 and the second substrate 30. The blocking component 210 may be disposed on the first substrate 10 and/or on the second substrate 30. There may be one or more blocking components 210.

Still referring to FIG. 1, in the embodiment, the cutting direction is the Y-axis direction. The second substrate 30 has a cutting edge 400 extending along the cutting direction. For example, the cutting edge 400 may be produced after cutting by a laser beam. In other words, the cutting edge 400 may be a laser cutting path, or may be an edge of the second substrate 30 produced by laser beam cutting. The blocking component 210 may be disposed to correspond to the cutting edge 400 along the cutting direction, that is, at least a portion of the blocking component 210 overlaps with the cutting edge 400.

In some embodiments, the source of the laser beam may be a gas laser source, a solid laser source, a semiconductor laser source, or another suitable laser source. For example, the laser source may be Ar⁺, ruby, YAG (neodymium-doped yttrium aluminum ruby), CO₂ laser source, but it is not limited thereto.

Since the electronic device of the present disclosure is provided with the blocking component 210 corresponding to the cutting edge 400, when the laser beam performs laser cutting along the cutting edge 400, the integrity of the non-cutting region under the blocking component 210 may be ensured.

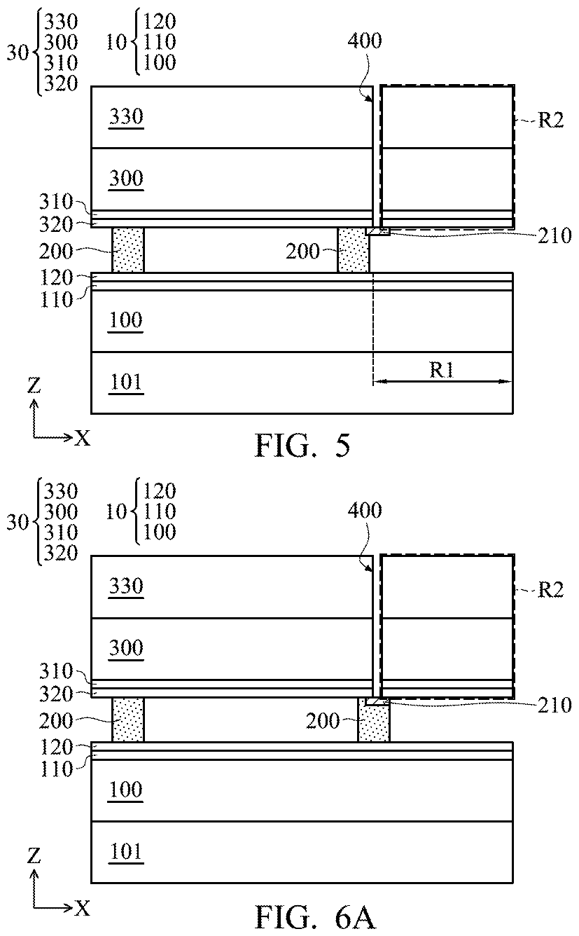

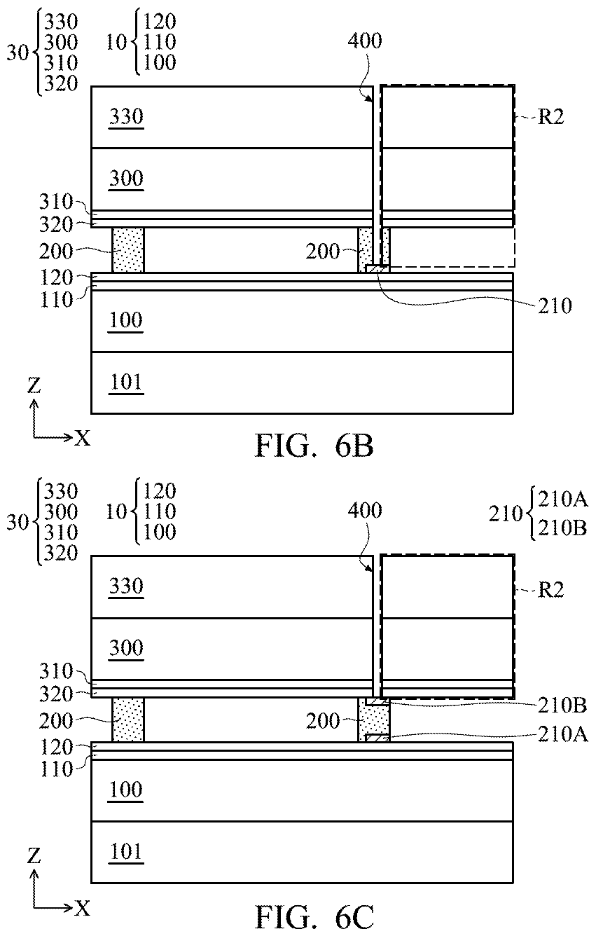

As shown in FIG. 1, the electronic device 1 may further include an encapsulation adhesive 200. In some embodiments, the encapsulation adhesive 200 may not overlap with the blocking component 210. Specifically, the encapsulation adhesive 200 may be separated from the blocking component 210 by a distance D. The distance D may be adjusted according to the requirements of users. In some embodiments, the distance D between the encapsulation adhesive 200 and the blocking component 210 is used to maintain the integrity of the encapsulation adhesive 200. However, in some other embodiments, at least a portion of the blocking component 210 may overlap with the encapsulation adhesive 200 (as shown in FIG. 5). Specifically, the encapsulation adhesive 200 may be in contact with the blocking component 210, or at least a portion of the blocking component 210 may be disposed in the encapsulation adhesive 200 (as shown in FIGS. 6A to 6C). In some embodiments, the blocking component 210 is embedded in the encapsulation adhesive 200. That is, a projection of the blocking component 210 on the first substrate 10 may be completely located in a projection of the encapsulation adhesive 200 on the first substrate 10 when viewed along the top view direction (Z direction), as shown in FIG. 6C, but the disclosure is not limited thereto. In the following, different embodiments will be used to describe the corresponding positions of the encapsulation adhesive 200 and the blocking component 210.

It should be noted that, as shown in FIG. 1, the second substrate 30 covers a portion of the blocking component 210 and exposes a portion of the blocking component 210. Therefore, the electronic device 1 shown in FIG. 1 shows that a region R2 of the second substrate 30 above the blocking component 210 is removed and a portion of the first substrate 10, which may be a bonding region R1 is exposed. In other words, the electronic device 1 shown in FIG. 1 is a schematic top view of the electronic device, wherein an omittable region is removed and a bonding region R1 for bonding with other features is left after a laser cutting process is performing by a laser beam. The above mentioned region and the bonding region R1 will be described further.

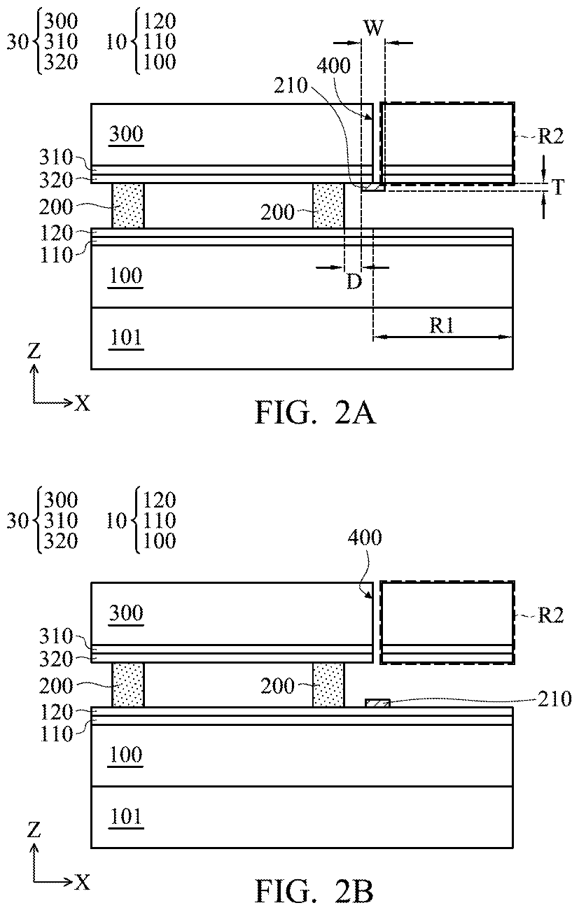

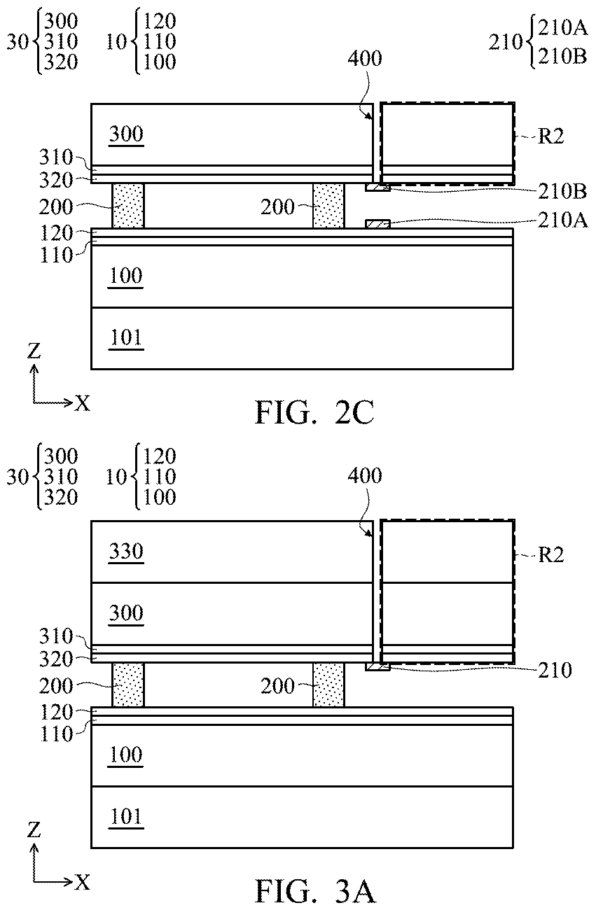

Referring to FIGS. 2A to 2C, which are schematic cross-sectional views of an electronic device 1 according to some embodiments of the present disclosure, wherein the encapsulation adhesive 200 does not overlap the blocking component 210. FIGS. 2A to 2C are schematic cross-sectional views taken along the line AA of FIG. 1.

As shown in FIG. 2A, the encapsulation adhesive 200 may be disposed between the first substrate 10 and the second substrate 30. The encapsulation adhesive 200 may be used to encapsulate a liquid crystal material in the electronic device of the present disclosure. In some embodiments, the above mentioned liquid crystal material may include nematic, smectic, cholesteric, blue phase or any other suitable liquid crystal material, but it is not limited thereto.

Therefore, the electronic device of the present disclosure may be a liquid crystal display, such as a thin film transistor liquid crystal display. Alternatively, the liquid crystal display may be a twisted nematic (TN) liquid crystal display, a super twisted nematic (STN) liquid crystal display, a double layer super twisted nematic (DSTN) liquid crystal display, vertical alignment (VA) liquid crystal display, multi-domain vertical alignment (MVA) liquid crystal display, in-plane switching (IPS) liquid crystal display, fringe field switching (FFS) liquid crystal display, cholesteric liquid crystal display, blue phase liquid crystal display or any other suitable liquid crystal display, but not limited thereto.

In some embodiments, the blocking component 210 may include a metal material. The metal material includes aluminum, copper, gold, silver, an alloy thereof, a combination thereof, or another suitable metal, but it is not limited thereto. In some embodiments, the reflectivity of the blocking component 210 to the laser beam is substantially equal to or greater than 80%. Therefore, the metal material included in the blocking component 210 may be any metal material with a reflectivity of 80% or more to the laser beam. For example, the reflectivity may substantially be equal to or greater than 88%, or it may substantially be equal to or greater than 95%. If the reflectivity of the blocking component 210 to the laser beam is less than 80%, it may be difficult for the blocking component 210 to effectively block the energy of the laser beam, or it may be difficult to effectively reflect the laser beam, which may result in damage to the non-cutting region under the blocking component 210.

In some embodiments, the non-cutting region may be at least a portion or all of the first substrate 10. In some embodiments, the non-cutting region may include at least a portion or all of the first base 100, a metal layer 110, an insulating layer 120, and/or any other layer under the blocking component 210. In other words, the non-cutting region may be any region that is not damaged and/or cut during the laser cutting process. In some embodiments, a portion of the non-cutting region may be, for example, the bonding region R1. For example, an outer lead bonding may be disposed on the bonding region R1, but the disclosure is not limited thereto.

In some embodiments, the blocking component 210 has a width W along the X-axis direction. The width W may be 10 μm to 400 μm (inclusive), or 10 μm to 200 μm (inclusive). Therefore, the probability of the electronic device being damaged by external static electricity may be reduced. In some embodiments, the cutting edge 400 is an edge of the second substrate 30. In some embodiments, when viewed in a cross-sectional view, the width from one end of the blocking component 210 to the cutting edge 400 along the X-axis direction and the width from the other end of the blocking component 210 to the cutting edge 400 along the X-axis direction may be substantially the same, and are about 5 μm to 200 μm (inclusive). That is, a virtual extending line of the cutting edge 400 of the second substrate 30 may evenly divide the width W of the blocking component 210, so that the electronic device has a good process window for the laser cutting process. However, it should be particularly noted that in the present disclosure, the blocking component 210 is disposed so that it corresponds to the cutting edge 400. That is, once the virtual extending line of the cutting edge 400 falls within the range of the width W of the blocking component 210, the blocking component 210 can protect the non-cutting region under the blocking component 210. In other words, the width from one end of the blocking component 210 to the cutting edge 400 along the X-axis direction and the width from the other end of the blocking component 210 to the cutting edge 400 along the X-axis direction may be substantially different.

In some embodiments, the blocking component 210 has a thickness T along the Z-axis direction. The thickness T may be 500 Å to 15000 Å (inclusive), or 500 Å to 10000 Å (inclusive). Therefore, the purpose of preventing the energy of the laser beam from damaging the non-cutting region under the blocking component 210 may be achieved. If the thickness T of the blocking component 210 is less than 500 Å, the blocking component 210 may be difficult to effectively block the laser beam, resulting in the possibility of damaging the non-cutting region under the blocking component 210.

Since the blocking component 210 is provided in the electronic device of the present disclosure, when the laser cutting process is performed by using a laser beam along the cutting edge 400, the excess energy of the laser beam will be reflected by the blocking component 210, thereby reducing the area of the non-cutting region which is thermally damaged by the excessive laser energy. Besides, when the laser power for cutting the second substrate 30 is increased, the integrity of the non-cutting region under the second substrate 30, that is the non-cutting region under the blocking component 210, still be ensured. Therefore, the electronic device including the blocking component of the present disclosure may provide a good process window for the laser cutting process, and therefore has excellent reliability.

As shown in FIG. 2A, the electronic device may further include a sacrificial layer 101 disposed under the first substrate 10. The sacrificial layer 101 may be a rigid material to support the first substrate 10 disposed thereon. The sacrificial layer 101 may be glass, ceramic, plastic, or any other suitable material, but it is not limited thereto. In some embodiments, the sacrificial layer 101 may be glass. In some embodiments, the first substrate 10 includes a bonding region R1. In some embodiments, an outer lead bonding may be disposed on the bonding region R1 of the first substrate 10, and the electronic device of the present disclosure is electrically connected to the external wiring through the outer lead bonding.

The first substrate 10 may further include a first base 100, a metal layer 110 disposed on the first base 100, and an insulating layer 120 disposed on the metal layer 110. A portion of the metal layer 110 may be used as a TFT array. The other portion of the metal layer 110 may be used as a wiring layer for connecting the above-mentioned TFT array. In some embodiments, the metal layer 110 may be a single layer or a multilayer structure. The insulating layer 120 may be used to make the alignment of the liquid crystal material uniform, reduce the coupling capacitance, and/or reduce the burden of the data line provided in the electronic device. The insulating layer 120 may include plastic, photoresist, or another suitable material. For example, the insulating layer 120 may include an acrylate material, an epoxy acrylate material, a siloxane material, or a combination thereof. In some embodiments, the insulating layer 120 may have a function of planarizing the surface of the first substrate 10, but the disclosure is not limited thereto. In some embodiments, other film layers may be disposed on, in, or under the first substrate 10. In other words, other film layers may be disposed on the first base 100, but the disclosure is not limited thereto.

The second substrate 30 may further include a second base 300, a black matrix layer 310 disposed on the second base 300, and an over coat (insulating) layer 320 disposed on the black matrix layer 310. That is, the black matrix layer 310 may be disposed between the coat layer 320 and the second base 300. The black matrix layer 310 may be used to define sub-pixels or pixel regions of the electronic device. For example, the black matrix layer 310 is disposed on a surface of the second substrate 30 facing the first substrate 10, but it is not limited thereto. The black matrix layer 310 may include black photoresist, black printing ink, black resin, or any other suitable black matrix material, but it is not limited thereto. The over coat layer 320 may include organic insulating materials such as photosensitive resin, or inorganic insulating materials such as silicon nitride, silicon oxide, silicon oxynitride, silicon carbide, aluminum oxide, or a combination thereof, but it is not limited thereto. In some embodiments, the over coat layer 320 may have the function of protecting other film layers disposed between the second base 300 and the over coat layer 320. In some embodiments, other film layers may be disposed on, in, or under the second substrate 30. In other words, other film layers may be provided on the second base 300, but the present disclosure is not limited thereto. In other embodiments, the second substrate 30 may not include the black matrix layer 310 and/or the over coat layer 320, but the present disclosure is not limited thereto.

As shown in FIG. 2A, the blocking component 210 may be disposed on the surface of the second substrate 30 facing the first substrate 10. For example, the blocking component 210 may be disposed on the over coat layer 320. The over coat layer 320 may be located between the blocking component 210 and the black matrix layer 310. The blocking component 210 may be disposed adjacent to the encapsulation adhesive 200. A portion of the blocking component 210 may be disposed between the encapsulation adhesive 200 and the extending line of the cutting edge 400. It should be noted that, in the case of the first substrate 10 further including a first base 100, a metal layer 110, and an insulating layer 120, and the second substrate 30 further including a second base 300, a black matrix layer 310, and an over coat layer 320, the blocking component 210 may be disposed between the first substrate 10 and the second substrate 30 and between the insulating layer 120 and the over coat layer 320. In other words, in some embodiments, the first substrate 10 includes a multi-layer film, that is, other single-layer or multi-layer films are provided on the first base 100, the blocking component 210 is provided between the outermost layer of the aforementioned single-layer or multi-layer film and the second substrate 30. In some embodiments, the second substrate 30 includes a multi-layer film, that is, other single-layer or multi-layer film are provided on the second base 300, the blocking component 210 is provided between the outermost layer of the aforementioned single-layer or multi-layer film and the first substrate 10. In some embodiments, the first substrate 10 includes a multi-layer film, and the second substrate 20 includes a multi-layer film, that is, a single-layer or multi-layer films are provided on the first base 100 and another single-layer or multi-layer films are provided on the second base 300. The blocking component 210 is provided between the outermost layer of the single-layer or multi-layer film and the outermost layer of the other single-layer or multi-layer film. In some embodiments, the outermost layer is the layer closest to the blocking component 210 during the face-to-face bonding process. In some embodiments, the outermost layer may be a protective layer, an insulating layer, an encapsulation layer, a functional layer, and/or a passivation layer, but the disclosure is not limited thereto.

In some embodiments, the cutting edge 400 extends from the second base 300 to the over coat layer 320 until it contacts the blocking component 210. Therefore, the position of the blocking component 210 can control an extending depth of the laser beam along the Z-axis direction during the laser cutting process. Therefore, the cutting depth of the laser cutting process can be easily controlled by adjusting the position of the blocking component 210 in the electronic device.

Here, the detailed process of forming the electronic device and performing the laser cutting process of the electronic device is described. It should be noted that in order to concisely explain the concept of the present disclosure, the main elements are listed, so for a person of ordinary skill in the art may dispose other elements.

First, a sacrificial layer 101 is provided. The sacrificial layer 101 is used as a carrier, and the first substrate 10 is disposed on the sacrificial layer 101. The first substrate 10 may include a first base 100 and a TFT array disposed on the first base 100, and any other suitable components. The metal layer 110 and the insulating layer 120 may be sequentially disposed on the first base 100 according to requirements.

On the other hand, another sacrificial layer (not shown) is provided and used as a carrier. The second substrate 30 is disposed on the sacrificial layer. The second substrate 30 may include a second base 300. The black matrix layer 310 and an over coat layer 320 may be sequentially disposed on the second base 300 according to requirements.

Then, the blocking component 210 is further disposed on the over coat layer 320, that is, the blocking component 210 is disposed on the second substrate 30. Next, the second substrate 30 and the first substrate 10 are face-to-face and bonded by the encapsulation adhesive 200. A liquid crystal material is poured into the space formed by the second substrate 30, the first substrate 10, and the encapsulation adhesive 200. That is, the first substrate 10 and the second substrate 30 are subjected to a face-to-face bonding process. Wherein, as shown in FIG. 2A, the bonding direction of the face-to-face bonding process is a direction of face-to-face bonding a surface of the over coat layer 320 away from the second base 300 with a surface of the insulating layer 120 away from the first base 100, so that the blocking component 210 is disposed between the over coat layer 320 and the insulating layer 120. Then, the sacrificial layer (not shown) on the second substrate 30 is removed. In some embodiments, after removing the sacrificial layer on the second substrate 30, a polarizer may be optionally disposed on the second substrate 30.

The laser cutting process is performed to obtain the required electronic devices. A laser beam is applied to the cutting edge 400, so that the laser beam passes through the second base 300, the black matrix layer 310, and the over coat layer 320 on the blocking component 210, in order to cut the second base 300, the black matrix layer 310, and the over coat layer 320. However, when the laser beam hits the blocking component 210, the laser beam is blocked and cannot continue cutting. Therefore, the blocking component 210 can excellently protect all features under the blocking component 210. The laser cutting process of the present disclosure may be, for example, a laser half-cut process, but the present disclosure is not limited thereto.

Next, the region R2 is removed to expose a portion of the first substrate 10, and the exposed portion of the first substrate 10 is the bonding region R1. The bonding region R1 may include the outer lead bonding disposed thereon. In some embodiments, by disposing the blocking component 210, during the laser cutting process, the energy of the laser beam is reduced, or a portion of the laser beam is reflected to prevent the laser beam from damaging the non-cutting region, thereby improving the process window of the laser cutting process. At the same time, the position of the cutting edge 400 is accurately controlled, so the size of the region R2 in the X direction may also be effectively reduced. Thus, the size of the liquid crystal material contained in the electronic device is increased, and a larger effective area is obtained. In addition, the size of the corresponding bonding region R1 may be reduced, and the size of the periphery region can be reduced.

In some embodiments, the blocking component 210 may serve as a component for blocking the laser beam. Also, the blocking component 210 may electrically connect with other features and/or serve as a heat sink. For example, the blocking component 210 may also be used as a metal component for signal transmission. The blocking component 210 may improve the heat dissipation performance of the electronic device.

In some embodiments, after performing the laser cutting process, the sacrificial layer 101 may be removed. The method of removing the sacrificial layer 101 may include laser removal, but it is not limited thereto.

In other embodiments, the position and number of the blocking component 210 may be changed. As shown in FIG. 2B, the blocking component 210 may be disposed on the insulating layer 120, and the insulating layer 120 may be located between the blocking component 210 and the metal layer 110. In this case, after respectively manufacturing the second substrate 30 and the first substrate 10, the blocking component 210 is disposed on the first substrate 10, and then the second substrate 30 and the first substrate 10 are subjected to a face-to-face bonding process.

As shown in FIG. 2C, the blocking component 210 may include a first sub-blocking component 210A and a second sub-blocking component 210B. The first sub-blocking component 210A is disposed on the insulating layer 120, and the insulating layer 120 may be located between the first sub-blocking component 210A and the metal layer 110. The second sub-blocking component 210B may be disposed on the over coat layer 320, and the over coat layer 320 may be located between the second sub-blocking component 210B and the black matrix layer 310. The first sub-blocking component 210A may be disposed closer to the first substrate 10 compared to the second sub-blocking component 210B. In this case, after respectively manufacturing the second substrate 30 and the first substrate 10, the first sub-blocking component 210A and the second sub-blocking component 210B are respectively disposed on the first substrate 10 and the second substrate 30. Then, the first substrate 10 and the second substrate 30 are subjected to a face-to-face bonding process. It should be noted that, in cases where a single blocking component 210 is provided, the electronic device including the blocking component of the present disclosure has the function of blocking the laser beam damaging features. However, a plurality of blocking components 210 may be further provided to further improve the reliability of the electronic device and the process window of the laser cutting process.

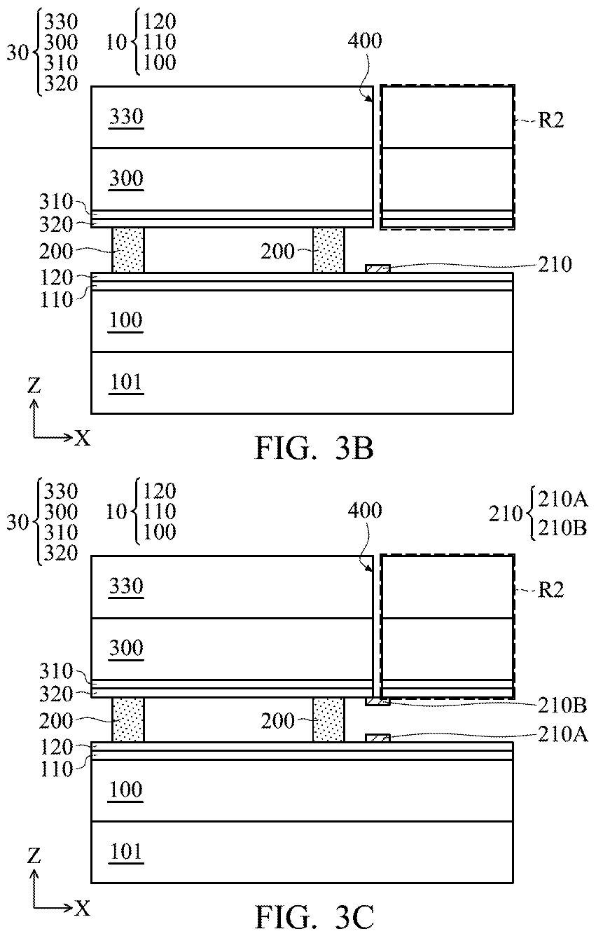

Referring to FIGS. 3A to 3C, the illustrated embodiment is an embodiment in which a cover layer 330 is further provided in an electronic device. The second substrate 30 may further include a cover layer 330 disposed on the second base 300. In detail, the second base 300 is disposed between the cover layer 330 and the first substrate 10. The cover layer 330 may be a polarizer to filter the light emitted from the electronic device and convert the light into a polarized light. The polarizer may include polyvinyl alcohol (PVA), triacetate cellulose (TAC) film, or any other suitable polarizing material.

As shown in FIG. 3A, the blocking component 210 may be disposed on the second substrate 30 to correspond to the first substrate 10. In some embodiments, the blocking component 210 may be disposed on a surface of the over coat layer 320 away from the second base 300. In some embodiments, the blocking component 210 may be adjacent to the encapsulation adhesive 200, and the blocking component 210 and the encapsulation adhesive 200 are separated by a distance. As shown in FIG. 3B, the blocking component 210 may be disposed on the first substrate 10 to correspond to the second substrate 30. In some embodiments, the blocking component 210 may be disposed on a surface of the insulating layer 120 away from the first base 100. In some embodiments, the blocking component 210 may be adjacent to the encapsulation adhesive 200, and the blocking component 210 and the encapsulation adhesive 200 are separated by a distance. As shown in FIG. 3C, the blocking component 210 may be provided on the first substrate 10 and the second substrate 30 at the same time. In other words, the blocking component 210 may be provided in plural. In some embodiments, the blocking component 210 may include a first sub-blocking component 210A and a second sub-blocking component 210B. The first sub-blocking component 210A may be disposed on a surface of the insulating layer 120 away from the first base 100. The second sub-blocking component 210B may be disposed on a surface of the over coat layer 320 away from the second base 300. The first sub-blocking component 210A and the second sub-blocking component 210B may be provided correspondingly.

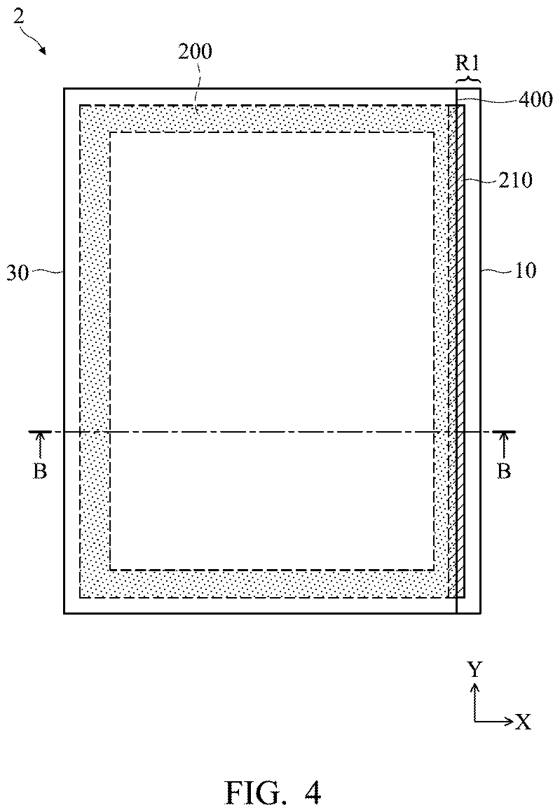

Referring to FIG. 4, which is a schematic top view of the electronic device 2 according to the present disclosure, wherein the encapsulation adhesive 200 and the blocking component 210 are overlapped. As shown in FIG. 4, when viewed in the top view direction (Z direction), at least a portion of the blocking component 210 overlaps the encapsulation adhesive 200. In order to reduce the size of the encapsulation adhesive 200 in the electronic device and realize a small-sized electronic device, the encapsulation adhesive 200 and the blocking component 210 may be overlapped.

Referring to FIG. 5, which is a schematic cross-sectional view taken along the line BB of FIG. 4. As shown in FIG. 5, the encapsulation adhesive 200 overlaps a portion of the blocking component 210, and the overlapping portion of the encapsulation adhesive 200 and the blocking component 210 does not overlap with the cutting edge 400, so the encapsulation adhesive 200 will not be cut during laser cutting process. In this case, after respectively manufacturing the second substrate 30 and the first substrate 10, the blocking component 210 is disposed on the second substrate 30. Then, the first substrate 10 and the second substrate 30 are subjected to a face-to-face bonding process so as to make the encapsulation adhesive 200 overlap with a portion of the blocking component 210.

Referring to FIGS. 6A to 6C, which are schematic cross-sectional views of an electronic device according to the present disclosure, wherein the blocking component 210 is provided in the encapsulation adhesive 200. The embodiments shown in FIGS. 6A to 6C are embodiments in which the blocking component 210 is provided in the encapsulation adhesive 200 of the electronic device. The blocking component 210 may be embedded in the encapsulation adhesive 200. It should be noted that, as shown in FIG. 6B, after performing the laser cutting process, a portion of the encapsulation adhesive 200 is cut. Thus, the region R2 which will be removed includes a portion of the encapsulation adhesive 200. However, a remaining portion of the encapsulation adhesive 200 is still effective enough to encapsulate the liquid crystal material in the encapsulation adhesive 200.

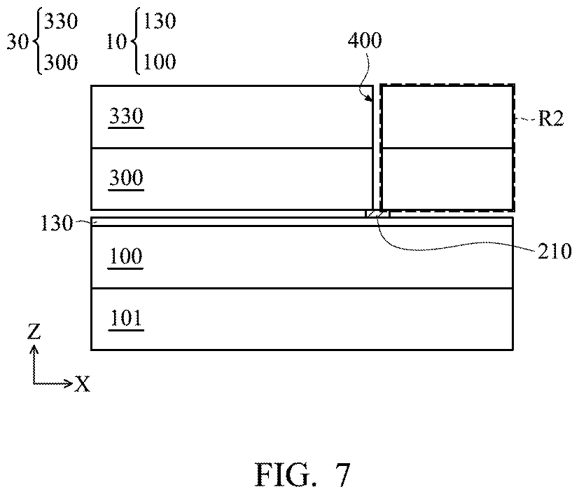

Referring to FIG. 7, which is a schematic cross-sectional view of an electronic device according to other embodiments of the present disclosure. The content that is the same as or similar to the foregoing content will not be repeated here. In this embodiment, the first substrate 10 may be disposed on the sacrificial layer 101. The first substrate 10 may be a flexible substrate and may include a first base 100. The first base 100 may include acryl based resin, polyimide based resin, benzocyclobutene based resin, any other suitable material, or a combination thereof. In some embodiments, the first substrate 10 may be a polyimide substrate. The first substrate 10 may include a TFT array, and an organic light emitting diode (OLED) is disposed on the TFT array. In some embodiments, the first substrate 10 may further include an encapsulation layer 130. The encapsulation layer 130 may be disposed on the first base 100 to encapsulate the above-mentioned organic light emitting diode. The material of the encapsulation layer 130 may include a single-layer or multi-layer structure of dielectric or insulating materials (such as silicon oxide, silicon nitride, aluminum oxide, or another suitable dielectric material). The second substrate 30 may include a second base 300. The second base 300 may be an optically clear adhesive (OCA) layer. In some embodiments, the second substrate 30 may further include a cover layer 330 disposed on the second base 300. The cover layer 330 may be a polarizer. For example, the above-mentioned polarizer may include organic materials or any other suitable polarizing materials. The blocking component 210 may be disposed between the first substrate 10 and the second substrate 30. In some embodiments, the blocking component 210 may be disposed on the encapsulation layer 130. The encapsulation layer 130 is disposed between the blocking component 210 and the first base 100. Therefore, the blocking component 210 can prevent the laser beam from damaging other features under the blocking component 210.

In some embodiments, a touch layer (not shown) may optionally be further provided on the encapsulation layer 130. In the case where a touch layer is provided on the encapsulation layer 130, the blocking component 210 may be provided on the touch layer. In other words, similar to the foregoing embodiments, when the first substrate 10 includes a multi-layer film and the second substrate 30 includes another multi-layer film, that is, other single-layer or multi-layer films are provided on the first base 100, and other single-layer or multilayer films are provided on the second base 300, the blocking component 210 is provided between the outermost layer of the single-layer or multilayer film on the first base 100 and the outermost layer of the single-layer or multilayer film on the second base 300. In some embodiments, portions of the first base 100 and the sacrificial layer 101 corresponding to the region R2 may be removed by the laser cutting process.

In summary, according to some embodiments of the present disclosure, when the laser half-cut is performed, the present disclosure can reduce the energy of the laser beam or reflect a portion of the energy of the emitted laser beam during the laser cutting process by disposing the blocking component corresponding to the cutting edge. Therefore, the electronic device including the blocking component of the present disclosure can prevent the laser beam from damaging the non-cutting region to improve the reliability of the electronic device. For example, when the electronic device including a blocking component of the present disclosure is cut by using a laser beam with strong energy, the process window of the laser cutting process can be improved and/or a high cutting yield is maintained. Furthermore, the present disclosure can more effectively improve the process window of the laser cutting process by providing a blocking component with a specific width, thickness, reflectivity, and/or a specific material.

On the other hand, after irradiating by the laser beam, the blocking component is not easily damaged by the laser beam. Thus, the blocking component can have other functions. For example, the blocking component can further serve as a heat sink, an interconnection feature, and/or a signal transmission feature. Besides, the present disclosure can further improve the process window of the laser cutting process and the reliability of the device by disposing a plurality of blocking components. Moreover, the electronic device including the blocking component of the present disclosure can increase the process window for the laser cutting process.

Although some embodiments of the present disclosure and their advantages have been disclosed, it should be understood that a person of ordinary skill in the art may change, replace, substitute and/or modify the present disclosure without departing from the spirit and scope of the present disclosure. In addition, the scope of the present disclosure is not limited to the manufacturing process, machine, manufacturing, material composition, device, method, and step in the specific embodiments described in the specification. A person of ordinary skill in the art will understand current and future manufacturing processes, machine, manufacturing, material composition, device, method, and step from the content disclosed in some embodiments of the present disclosure, as long as the current or future manufacturing processes, machine, manufacturing, material composition, device, method, and step performs substantially the same functions or obtain substantially the same results as the present disclosure. Therefore, the scope of the present disclosure includes the above-mentioned manufacturing process, machine, manufacturing, material composition, device, method, and steps. Moreover, each of the claims constitutes an individual embodiment, and the scope of the present disclosure also includes combinations of each of the claims and embodiments. The features among the various embodiments can be arbitrarily combined as long as they do not violate or conflict with the spirit of the disclosure.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. An electronic device, comprising:
a first substrate;
a second substrate, opposite to the first substrate, wherein the second substrate has a cutting edge extending along a cutting direction; and
a blocking component, disposed between the first substrate and the second substrate;
wherein the blocking component extends along the cutting direction and is disposed corresponding to the cutting edge.

2. The electronic device as claimed in claim 1, wherein the blocking component is disposed on the first substrate.

3. The electronic device as claimed in claim 1, wherein the first substrate comprises an encapsulation layer and a first base, and wherein the encapsulation layer is disposed between the blocking component and the first base.

4. The electronic device as claimed in claim 1, wherein the second substrate comprises a cover layer and a second base, and wherein the second base is disposed between the cover layer and the first substrate.

5. The electronic device as claimed in claim 1, further comprising:
an encapsulation adhesive, wherein the encapsulation adhesive is disposed between the first substrate and the second substrate.

6. The electronic device as claimed in claim 5, wherein at least a portion of the blocking component overlaps with the encapsulation adhesive.

7. The electronic device as claimed in claim 6, wherein the encapsulation adhesive overlaps with the cutting edge.

8. The electronic device as claimed in claim 6, wherein the encapsulation adhesive has a distance between the cutting edge.

9. The electronic device as claimed in claim 5, wherein the blocking component has a distance with the encapsulation adhesive.

10. The electronic device as claimed in claim 5, wherein the blocking component is disposed in the encapsulation adhesive.

11. The electronic device as claimed in claim 1, wherein the first substrate comprises a bonding region below the blocking component.

12. The electronic device as claimed in claim 1, wherein the blocking component comprises a first sub-blocking component and a second sub-blocking component, wherein the first sub-blocking component is disposed on the first substrate, and the second sub-blocking component is disposed on the second substrate.

13. The electronic device as claimed in claim 1, wherein the blocking component has a width of 10 μm to 400 μm.

14. The electronic device as claimed in claim 1, wherein the blocking component has a thickness of 500 Å to 15000 Å.

15. The electronic device as claimed in claim 1, wherein a reflectivity of the blocking component is equal to or greater than 80%.

16. The electronic device as claimed in claim 1, wherein the blocking component comprises a metal material.

17. The electronic device as claimed in claim 16, wherein the metal material comprises aluminum, copper, gold, silver, an alloy thereof, or a combination thereof.

18. The electronic device as claimed in claim 1, wherein the first substrate comprises a plurality of layers, and the blocking component is in contact with an outermost layer of the plurality of layers and the second substrate.

19. The electronic device as claimed in claim 1, wherein the second substrate comprises a plurality of layers, and the blocking component is in contact with an outermost layer of the plurality of layers and the first substrate.

20. The electronic device as claimed in claim 1, wherein the first substrate comprises a plurality of layers, the second substrate comprises another plurality of layers, and the blocking component is in contact with an outermost layer of the plurality of layers and an outermost layer of the other plurality of layers.
